(19) United States
(12) Patent Application Publication
(10) Pub. No.: US 2024/0215346 A1
(43) Pub. Date: Jun. 27, 2024

(54) DISPLAY DEVICE, DISPLAY PANEL AND MANUFACTURING METHOD THEREOF

(71) Applicants: YUNNAN INVENSIGHT OPTOELECTRONICS TECHNOLOGY CO., LTD., Yunnan (CN); BOE TECHNOLOGY GROUP CO., LTD., Beijing (CN)

(72) Inventors: Shengji YANG, Beijing (CN); Xue DONG, Beijing (CN); Hui WANG, Beijing (CN); Xiaochuan CHEN, Beijing (CN); Kuanta HUANG, Beijing (CN); Pengcheng LU, Beijing (CN); Dacheng ZHANG, Beijing (CN)

(21) Appl. No.: 17/913,789

(22) PCT Filed: Aug. 19, 2021
(86) PCT No.: PCT/CN2021/113639

§ 371 Date: Sep. 22, 2022

(51) Int. Cl. H10K 59/131; H10K 59/12; H10K 59/122; H10K 59/86

(52) U.S. Cl. CPC H10K 59/131; H10K 59/1201; H10K 59/122; H10K 59/86

(57) ABSTRACT

A display device, a display panel and manufacture method thereof, the display panel includes: a substrate, a wiring layer disposed at a side of the substrate; a conductive shielding layer disposed at the same side of the substrate as the wiring layer; a planar layer, covering the wiring layer and the conductive shielding layer; a first electrode layer, disposed on the planar layer and including a first electrode, wherein the first electrode is connected to a wiring layer through a first conductor; a pixel definition layer covering the planar layer; a light-emitting layer covering the pixel definition layer and the first electrode, and is connected to the conductive shielding layer through a second conductor; and a second electrode covering the light-emitting layer.

### CROSS REFERENCE

The present application is based upon International Application No. PCT/CN2021/113639, filed on Aug. 19, 2021, and the entire contents thereof are incorporated herein by reference.

### TECHNICAL FIELD

The present disclosure relates to the field of display technology, and in particular, to a display device, a display panel, and a manufacturing method of the display panel.

### BACKGROUND

With the development of display technology, display panels have been widely used in various electronic devices such as mobile phones to realize image display and touch operation. An OLED (Organic Light-Emitting Diode) display panel is a relatively common one.

It should be noted that, information disclosed in the above background portion is provided only for better understanding of the background of the present disclosure, and thus it may contain information that does not form the prior art known by those ordinary skilled in the art.

### SUMMARY

An object of the present disclosure is to provide a display device, a display panel, and a manufacturing method of the display panel.

According to an aspect of the present disclosure, there is provided a display panel, including:
a substrate;
at least one wiring layer, disposed at a side of the substrate;
a conductive shielding layer, disposed at the side of the substrate same as the wiring layer, and insulated from the wiring layer;
a planar layer, covering the wiring layer and the conductive shielding layer;
a first electrode layer, disposed at a surface of the planar layer away from the substrate, and including a plurality of first electrodes distributed at intervals and connected to one of the wiring layer through a first conductor disposed in the planar layer;
a pixel definition layer, covering the planar layer and exposing respective first electrode;
a light-emitting layer, covering the pixel definition layer and the first electrode, and is connected to the conductive shielding layer through a second conductor at least partially disposed in the planar layer, wherein an orthographic projection of the second conductor on the substrate is located outside an orthographic projection of the first electrode on the substrate; and
a second electrode, covering the light-emitting layer.

In an exemplary embodiment of the present disclosure, the pixel definition layer is provided with a separation groove recessed toward the substrate, and an orthographic projection of the separation groove on the substrate is located outside the orthographic projection of the first electrode on the substrate; and the light-emitting the layer is recessed at the separation groove; and
the second conductor is penetrated into the separation groove in a direction away from the substrate, and is embedded in the light-emitting layer.

In an exemplary embodiment of the present disclosure, the planar layer is provided with a groove, and an orthographic projection of the groove on the substrate is located outside the orthographic projection of the first electrode on the substrate; and
the pixel definition layer is extended to a sidewall and a bottom surface of the groove to form the separation groove.

In an exemplary embodiment of the present disclosure, the pixel definition layer is covered on a surface of the second conductor away from the substrate, and the pixel definition layer is intermittently disposed on the sidewall of the second conductor.

In an exemplary embodiment of the present disclosure, the planar layer is provided with a groove, and an orthographic projection of the groove on the substrate is located outside the orthographic projection of the first electrode on the substrate;
an orthographic projection of the pixel definition layer on the substrate is located outside the orthographic projection of the groove on the substrate; and the light-emitting layer is recessed at the groove; and
the second conductor is penetrated into the groove in a direction away from the substrate, and is embedded in the light-emitting layer.

In an exemplary embodiment of the present disclosure, the conductive shielding layer is disposed on a same layer as the one of the wiring layer.
the at least one wiring layer includes multiple wiring layers distributed in sequence along a direction away from the substrate; and adjacent two wiring layers are connected;
the one of the wiring layer furthest away from the substrate is a target wiring layer, and the target wiring layer is connected to the first electrode through the first conductor; and
the conductive shielding layer is disposed on a same layer as the target wiring layer.

In an exemplary embodiment of the present disclosure, in a direction perpendicular to the substrate, a length of the first conductor is greater than a length of the second conductor.

In an exemplary embodiment of the present disclosure, in a direction perpendicular to the substrate, a length of a portion of the second conductor located in the groove is smaller than a depth of the groove.

In an exemplary embodiment of the present disclosure, in a direction perpendicular to the substrate, a distance between a surface of the first conductor facing away from the substrate and a bottom surface of the groove is greater than the length of the portion of the second conductor located in the groove.

In an exemplary embodiment of the present disclosure, a bottom surface of the groove has an opening area and a peripheral area outside the opening area, the second conductor is passed through the opening area, and the peripheral area is protruded toward a side of the opening area facing away from the substrate.

In an exemplary embodiment of the present disclosure, in a direction perpendicular to the substrate, a height of the peripheral region protruding from the opening region is smaller than a height of a portion of the second conductor passing through over the planar layer.

In an exemplary embodiment of the present disclosure, the second conductor is provided in plural, and each of which is connected to the conductive shielding layer.

In an exemplary embodiment of the present disclosure, an area of a surface of the second conductor facing away from the substrate is smaller than an area of a surface of the first conductor facing away from the substrate.

In an exemplary embodiment of the present disclosure, in a direction perpendicular to the substrate, a length of the first conductor is equal to a length of the second conductor.

In an exemplary embodiment of the present disclosure, the conductive shielding layer is connected to the second electrode.

In an exemplary embodiment of the present disclosure, the conductive shielding layer includes a first conductive layer, a second conductive layer, and a third conductive layer that are sequentially stacked in a direction away from the substrate.

In an exemplary embodiment of the present disclosure, the first conductive layer and the third conductive layer are both formed of metal titanium, and the second conductive layer is formed of metal aluminum.

In an exemplary embodiment of the present disclosure, the light-emitting layer includes multiple layers of light-emitting sub-layers connected in series, and at least one of the light-emitting sub-layers is connected in series with an adjacent one of the light-emitting sub-layers through a charge generating layer.

In an exemplary embodiment of the present disclosure, the light-emitting layer is recessed to form a first recessed area in a region corresponding to the groove; and an area of a bottom surface of the first recessed area corresponding to the second conductor is protruded to form a first protruding area; and

the second electrode is recessed to form a second recessed area in an area corresponding to the first recessed area; and an area of a bottom surface of the second recessed area corresponding to the first protruding area is protruded to form a second protruding area.

According to an aspect of the present disclosure, there is provided a method for manufacturing display panel, including:
forming a substrate;
forming at a side of the substrate a conductive shielding layer, at least one wiring layer, a planar layer covering the wiring layer and the conductive shielding layer, a first conductor and a second conductor, wherein the conductive shielding layer is insulated from the wiring layer, the first conductor is disposed in the planar layer and connected to one of the wiring layer, and the second conductor is penetrated into the planar layer from a side of the planar layer away from the substrate and connected to the conductive shielding layer;
forming a first electrode layer at a surface of the planar layer away from the substrate, wherein the first electrode layer includes a plurality of first electrodes distributed at intervals, an orthographic projection of the conductive shielding layer on the substrate is spaced apart from an orthographic projection of the first electrode on the substrate, and the first electrode is connected to the first conductor;
forming a pixel definition layer covering the planar layer and exposing respective first electrode;
forming a light-emitting layer covering the pixel definition layer and the first electrode, wherein the light-emitting layer is connected to the second conductor; and
forming a second electrode covering the light-emitting layer.

In an exemplary embodiment of the present disclosure, after forming the first electrode layer and before forming the pixel definition layer, the method further includes:
forming a groove on the planar layer, wherein an orthographic projection of the groove on the substrate is outside the orthographic projection of the first electrode on the substrate, and the second conductor is penetrated into the groove in a direction away from the substrate;
wherein the pixel definition layer is extended to a sidewall and a bottom surface of the groove to form a separation groove; and the light-emitting layer is recessed at the separation groove.

In an exemplary embodiment of the present disclosure, after forming the first electrode layer and before forming the pixel definition layer, the method further includes:
forming a groove on the planar layer, wherein an orthographic projection of the groove on the substrate is outside the orthographic projection of the first electrode on the substrate, and the second conductor is penetrated into the groove in a direction away from the substrate;
wherein an orthographic projection of the pixel definition layer on the substrate is outside the orthographic projection of the groove on the substrate; and the light-emitting layer is recessed at the separation groove.

In an exemplary embodiment of the present disclosure, the forming at the side of the substrate the conductive shielding layer, at least one wiring layer, the planar layer covering the wiring layer and the conductive shielding layer, the first conductor and the second conductor includes:
forming the conductive shielding layer, at least one wiring layer and a first planar insulating layer covering the wiring layer and the conductive shielding layer at the side of the substrate;
forming a first via hole and a second via hole extending toward the substrate in the first planar insulating layer, wherein the one of the wiring layer is exposed by the first via hole, and the conductive shielding layer is exposed by the second via hole;
forming a first conductive portion in the first via hole, and forming the second conductor in the second via hole;
forming a second planar insulating layer covering the first planar insulating layer, wherein the planar layer includes the first planar insulating layer and the second planar insulating layer;
forming a third via hole in connection with the first via hole in the second planar insulating layer; and
forming a second conductive portion connected to the first conductive portion in the third via hole, wherein the first conductor includes the first conductive portion and the second conductive portion.

In an exemplary embodiment of the present disclosure, the forming at the side of the substrate the conductive shielding layer, at least one wiring layer, the planar layer covering the wiring layer and the conductive shielding layer, the first conductor and the second conductor includes:
forming the conductive shielding layer, at least one wiring layer and the planar layer covering the wiring layer and the conductive shielding layer at the side of the substrate;
forming a first via hole and a second via hole extending toward the substrate in the planar layer, wherein the one of the wiring layer is exposed by the first via hole, and the conductive shielding layer is exposed by the second via hole; and
forming the first conductor in the first via hole, and forming the second conductor in the second via hole.

In an exemplary embodiment of the present disclosure, the conductive shielding layer and the one of the wiring layer are formed simultaneously.

In an exemplary embodiment of the present disclosure, the at least one wiring layer includes multiple wiring layers distributed in sequence along a direction away from the substrate; and adjacent two wiring layers are connected;
the one of the wiring layer furthest away from the substrate is a target wiring layer, and the target wiring layer is connected to the first electrode through the first conductor; and
the conductive shielding layer and the target wiring layer are formed simultaneously.

According to an aspect of the present disclosure, there is provided a display device, including any one of the above display panel.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Obviously, the drawings in the following description are only some embodiments of the present disclosure, and for those of ordinary skill in the art, other drawings can also be obtained from these drawings without creative efforts.

FIG. 1 is a circuit schematic diagram of the leakage of the light-emitting unit in the related art.

FIG. 2 is a schematic structural diagram of the leakage current of the light-emitting unit in the related art.

FIG. 3 is a spectrogram of a light-emitting unit in the related art.

FIG. 4 is a schematic diagram of an embodiment of a display panel of the present disclosure.

FIG. 5 is a schematic diagram of an embodiment of a display panel of the present disclosure.

FIG. 6 is a schematic diagram of an embodiment of a display panel of the present disclosure.

FIG. 7 is a schematic diagram of a portion of the film layer of the embodiment of FIG. 6.

FIG. 8 is a schematic diagram of an embodiment of a display panel of the present disclosure.

FIG. 9 is a top view of a driving backplane in an embodiment of the disclosed display panel.

FIG. 10 is a schematic diagram of a light-emitting layer in an embodiment of the disclosed display panel.

FIG. 11 is a schematic diagram of a circuit for preventing electric leakage of the display panel of the present disclosure.

FIG. 12 is a spectrogram of an embodiment of the disclosed display panel.

FIG. 13 is a voltage-brightness schematic diagram of an embodiment of the disclosed display panel.

FIG. 14 is a schematic diagram of voltage-color coordinates of a red sub-pixel in an embodiment of the disclosed display panel.

FIG. 15 is a schematic diagram of voltage-color coordinates of a blue sub-pixel in an embodiment of the disclosed display panel.

FIG. 16 is a schematic diagram of voltage-color coordinates of a green sub-pixel in an embodiment of the disclosed display panel.

FIGS. 17-22 are schematic structural diagrams of some steps in an embodiment of a method for manufacturing a display panel of the present disclosure.

### DETAILED DESCRIPTION

Example embodiments will now be described more fully with reference to the accompanying drawings. Example embodiments, however, can be embodied in various forms and should not be construed as limited to the embodiments set forth herein; rather, these embodiments are provided so that this disclosure will be thorough and complete, and will fully convey the concept of example embodiments to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

The terms “a”, “an”, “the”, “said” and “at least one” are used to indicate the presence of one or more elements/components/etc.; the terms “include” and “have” are used to indicate an open-ended inclusive, and mean that additional elements/components/etc. may be present in addition to the listed elements/components/etc.; the terms “first”, “second” and “third” etc. are only used as a marker, rather than a limit on the number of objects.

In the related art, a Micro OLED display panel (Micro Organic Light-Emitting Diode) is a display panel developed in recent years, and the Micro OLED light-emitting devices contained therein usually have a size of less than 100 μm. Silicon-based OLED display panel is a relatively common one. Silicon-based OLED can not only realize active addressing of pixels, but also realize the preparation of COMS circuits including pixel circuits, timing control (TCON) circuits, overcurrent protection (OCP) circuits on the silicon substrate by semiconductor manufacturing processes, for reducing the size of the system and achieving light weight.

Taking a silicon-based OLED display panel as an example, it may include a driving backplane and a light-emitting layer, wherein: the light-emitting functional layer is provided on one side of the driving backplane, and includes a plurality of light-emitting devices, and the light-emitting unit may include one or more serially connected OLED light-emitting devices, each light-emitting device includes a first electrode (anode), a light-emitting layer and a second electrode (cathode) stacked in sequence in the direction away from the driving backplane, and by applying an electrical signal to the first electrode and the second electrode, the light-emitting layer can be driven to emit light, and the specific light-emitting principle of the OLED light-emitting device will not be described in detail here.

In addition, the light-emitting layer of each light-emitting device can be formed by direct vapor deposition through a fine mask (FMM). The light-emitting layers of each light-emitting device are distributed separately, emit light independently, and realize color display. However, it is difficult to achieve high PPI (pixel density) due to the limitations of the fine mask manufacturing process. Therefore, color display can also be realized by combining monochromatic light or white light with a color filter, that is, each light-emitting device shares the same continuous light-emitting layer, the light-emitting layer can emit white light or other monochromatic light. The color filter layer has a plurality of filter regions corresponding to the light-emitting units one-to-one. A filter region and the corresponding light-emitting units can constitute a sub-pixel, and a plurality of sub-pixels constitute a pixel. The colors of light that can pass through different filter regions can be different, so that the emission colors of different sub-pixels can be different. The same pixel includes a plurality of sub-pixels with different colors. For example, a pixel may include emission colors of red (R), green (G), and blue (B) sub-pixels. Thereby, color display can be realized by a plurality of pixels.

However, if the light-emitting layer is a continuous whole-layer structure, electricity leakage is likely to occur between a light-emitting unit and surrounding light-emitting units, resulting in cross-color.

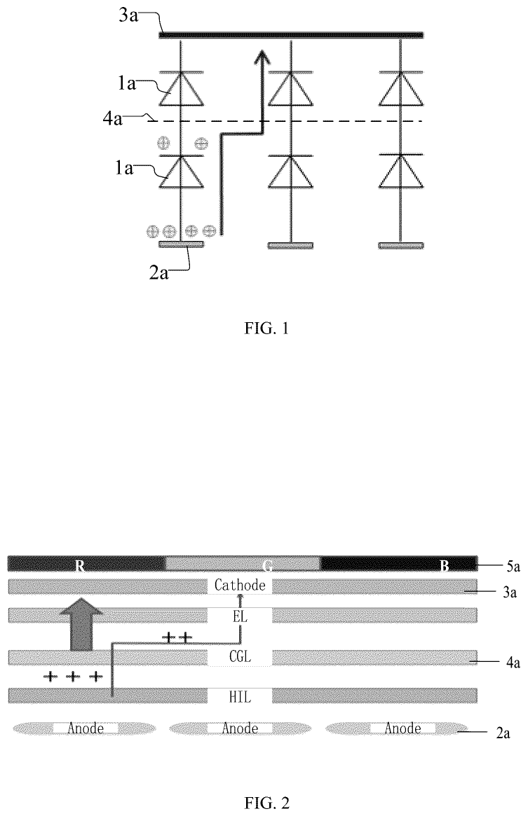

As shown in FIG. 1, each light-emitting unit may include two light-emitting devices connected in series, the two light-emitting devices share a first electrode 2a and a second electrode 3a, and there are two layers of light-emitting sublayers 1a between the first electrode 2a and the second electrode 3a, which are connected in series by the charge generating layer 4a to form a light-emitting layer. It can be seen from FIGS. 1 and 2 that positive charges (holes) are transferred between two adjacent light-emitting units through the charge generation layer 4a, and it can be seen from FIG. 2 that when the light-emitting unit corresponding to the red filter area R of the color filter layer 5a emits light, the light-emitting unit corresponding to the green filter area G of the color filter layer 5a may also emit light due to the influence of leakage, resulting in a decrease in the luminous purity of a single pixel and decreasing the color gamut of the entire display panel.

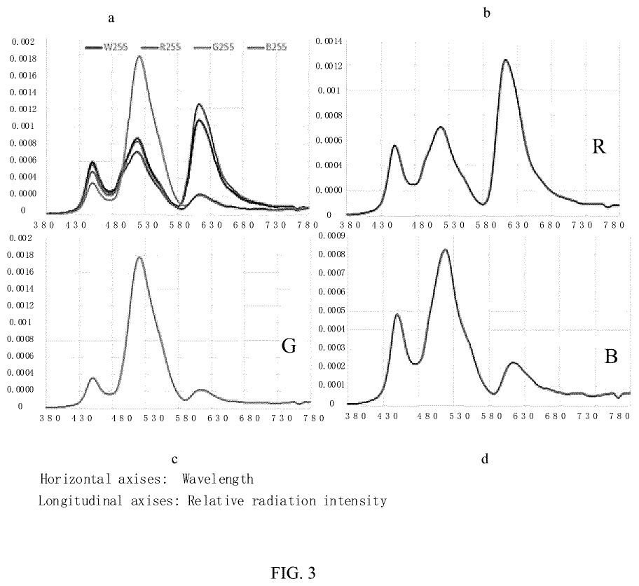

As shown in FIG. 3, which shows the spectrogram of the red (R), green (G), and blue (B) three sub-pixels in the same pixel lit at the same time (shown in a in FIG. 3) and the spectrogram when they are separately lit (shown in b-c in FIG. 3). According to the wavelength, it can be seen that when the three sub-pixels are lit respectively, light of different colors escapes from the adjacent sub-pixels. For example, as shown in a in FIG. 3, when the R sub-pixel emits red light, peaks exist at the wavelengths corresponding to blue light and green light, that is, which are emitted by blue light and green light. This results in a reduction in the color gamut of the entire display panel. According to calculations, the color gamut index (NTSC) of the display panel is only 30%.

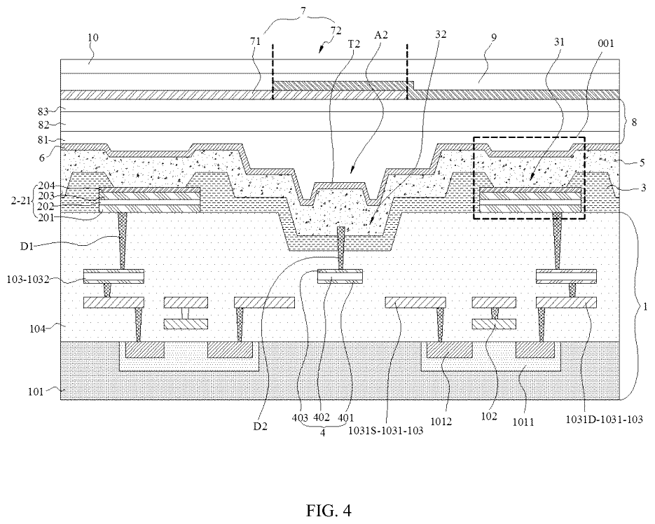

Embodiments of the present disclosure provide a display panel. As shown in FIGS. 4-9, the display panel may include a driving backplane 1, a first electrode layer 2, a pixel definition layer 3, a light-emitting layer 5, a second electrode 6 and a color filter layer 7.

The driving backplane 1 includes a substrate 101, a conductive shielding layer 4, at least one wiring layer 103 on one side of the substrate 101, and a planar layer 104 covering the wiring layer 103 and the conductive shielding layer 4. The conductive shielding layer 4 is insulated from the respective wiring layer 103.

The first electrode layer 2 is provided on the surface of the planar layer 104 away from the substrate 101 and includes a plurality of first electrodes 21 distributed at intervals. The orthographic projection of the first electrodes 21 on the substrate 101 is spaced apart from the orthographic projection of the conductive shielding layer 4 on the substrate 101. The first electrode 21 is connected to a wiring layer 103 through the first conductor D1 in the planar layer 104.

The pixel definition layer 3 covers the planar layer 104 and exposes the respective first electrodes 21. The light-emitting layer 5 covers the pixel definition layer 3 and the first electrode 21, and is connected to the conductive shielding layer 4 through a second conductor D2 disposed at least partially within the planar layer 104. The second electrode 6 covers the light-emitting layer 5.

In the display panel of the embodiment of the present disclosure, any first electrode 21 and its corresponding light-emitting layer 5 and second electrode 6 may constitute a light-emitting unit 001. Since the orthographic projection of the conductive shielding layer 4 on the substrate 101 is outside the orthographic projection of the wiring layer 103 on the substrate 101, and is connected to the light-emitting layer 5 through the second conductor D2, therefore the carriers (e.g. holes) generated in the light-emitting layer 5 and moving along the distribution direction of the first electrode 21 can be absorbed by the conductive shielding layer 4 to prevent leakage between the light-emitting units 001, thereby improving cross color.

The structure for realizing the display function of the display panel of the present disclosure will be described in detail below.

As shown in FIGS. 4-9, the driving backplane 1 may include a pixel area 110 and a peripheral area 120, and the peripheral area 120 is located outside the pixel area 110 and may be disposed around the pixel area 110. The driving backplane 1 is used to form a driving circuit for driving the light-emitting unit 001 to emit light, and the driving circuit may include a pixel circuit and a peripheral circuit.

The number of pixel circuits and light-emitting units 001 can be multiple, and the pixel circuits are located in the pixel area 110. The pixel circuits can be pixel circuits such as 2TIC, 4T2C, 6TIC, or 7TIC, as long as the light-emitting unit 001 can be driven to emit light. There is no special restriction on its structure. The number of pixel circuits is the same as that of the first electrodes 21, and is connected to the first electrodes 21 in a one-to-one correspondence, so as to control the light-emitting units 001 to emit light respectively. In the disclosure, nTmC indicates that a pixel circuit includes n transistors (represented by the letter “T”) and m capacitors (represented by the letter “C”).

The peripheral circuit is located in the peripheral area 120 and is connected to the pixel circuit. The peripheral circuit may include at least one of a light-emitting control circuit, a gate electrode 102 driving circuit, a source driving circuit, and a power supply circuit, and of course other circuits may be included, as long as the light-emitting unit 001 can be driven to emit light through the pixel circuit. At the same time, the peripheral circuit may further include a power supply circuit connected to the second electrode 6 for inputting a power supply signal to the second electrode 6. The peripheral circuit can input a driving signal to the first electrode 21 and a power supply signal to the second electrode 6 through the pixel circuit, so that the light-emitting unit 001 emits light.

In some embodiments of the present disclosure, as shown in FIGS. 4-8, the substrate 101 may be a silicon substrate, and the above-mentioned driving circuit may be formed on the silicon substrate by a semiconductor process. For example, the pixel circuit and the peripheral circuit may both include a plurality of transistors, a well region 1011 can be formed in a silicon substrate through a doping process, and the well region 1011 has two doping regions 1012 spaced apart. Meanwhile, taking a well region 1011 as an example: the gate electrode 102 is provided on one side of the driving backplane 1, that is, the orthographic projection of the gate electrode 102 on the substrate 101 is located between the two doped regions 1012. At least one wiring layer 103 is connected to the doped regions 1012, and one wiring layer 103 may include a source electrode 1031S and a drain electrode 1031D connected to the two doped regions 1012 of the same well region 1011.

For example, the number of the wiring layers 103 is two and located in the planar layer 104. For example, the wiring layer 103 includes a first wiring layer 1031 and a second wiring layer 1032, and the first wiring layer 1031 is disposed at a side of the substrate 101 with a part of the planar layer 104 disposed between first wiring layer 1031 and the substrate 101. The first wiring layer 1031 includes a source electrode 1031S and a drain electrode 1031D, and the source electrode 1031S and drain electrode 1031D of the same transistor are connected respectively to the two doped regions 1012 of 1011 of the same well region, so that a transistor can be formed by a well region 1011 and its corresponding gate electrode 102, source electrode 1031S and drain electrode 1031D. The second wiring layer 1032 is disposed at the side of the first wiring layer 1031 away from the substrate 101, and is separated from the first wiring layer 1031 by a part of the planar layer 104. At least a part region of the second wiring layer 1032 is connected to the first wiring layer 1031. The driving circuit may be formed by connecting the transistors through the respective wiring layer 103. The specific connection routes and wiring patterns may depend on the circuit structure and are not particularly limited here.

Each wiring layer 103 may be formed by a sputtering process. The material of the planar layer 104 may be silicon oxide, silicon oxynitride or silicon nitride, which is formed layer by layer through multiple deposition and polishing processes. That is, the planar layer 104 can be formed by stacking multiple insulating film layers.

As shown in FIG. 4 to FIG. 8, the light-emitting units 001 of the display panel are arranged in an array on one side of the driving backplane 1, for example, the light-emitting units 001 are disposed on the surface of the planar layer 104 away from the substrate 101. Each light-emitting unit 001 may include a first electrode 21, a second electrode 6 and a light-emitting layer 5 located between the first electrode 21 and the second electrode 6, and both the first electrode 21 and the second electrode 6 may be connected to the wiring layer 103. Through driving the backplane 1, the driving signal is applied to the first electrode 21 and the power signal is applied to the second electrode 6, so as to drive the light-emitting layer 5 to emit light.

In order to realize color display, each light-emitting unit 001 can emit light of the same color, and cooperate with the color filter layer 7 located on the side of the second electrode 6 away from the substrate 101 to realize color display. The embodiments of the present disclosure will be described by taking such a color display scheme as an example. Of course, each light-emitting unit 001 can also be made to emit light independently, and the light-emitting colors of different light-emitting units 001 can be different.

In some embodiments of the present disclosure, as shown in FIGS. 4-9, a plurality of light-emitting units 001 may be formed by the first electrode layer 2, the pixel definition layer 3, the light-emitting layer 5 and the second electrode 6.

The first electrode layer 2 is disposed on the surface of the planar layer 104 facing away from the substrate 101. The first electrode layer 2 may include a plurality of first electrodes 21 distributed at intervals, and the orthographic projection of each first electrode 21 on the substrate 101 is located in the pixel region 110. The first electrodes 21 are connected to the pixel circuit, and one first electrode 21 is connected to one pixel circuit.

For a plurality of wiring layers 103, the first electrode 21 can be connected to the wiring layer 103 with the largest distance from the substrate 101. For example, a first via hole exposing a wiring layer 103 can be formed on the planar layer 104, and a first conductor D1 is formed in the first via hole. The first electrode 21 covers the first via hole and is connected to the wiring layer 103 through the first conductor D1, thereby connecting the first electrode 21 to the pixel circuit.

In some embodiments of the present disclosure, as described above, the wiring layer 103 includes a first wiring layer 1031 and a second wiring layer 1032, and the first electrode 21 may be connected to the second wiring layer 1032 through the first conductor D1 located in the first via hole.

The first electrode layer 2 may have a single-layer or multi-layer structure, and its material is not particularly limited herein. For example, the first electrode layer 2 may include a first layer 201, a second layer 202, a third layer 203 and a fourth layer 204 that are sequentially stacked in a direction away from the substrate 101, wherein the first layer 201 and the third layer 203 may be formed of the same metal material, such as titanium, the fourth layer 204 may be formed of a transparent conductive material such as ITO (indium tin oxide), and the second layer 202 may be formed of a metal material different from the first layer 201, the third layer 203 and the fourth layer 204, having the resistivity lower than the first layer 201 and the third layer 203. For example, the material of the second layer 202 may be aluminum.

As shown in FIGS. 4 to 8, the pixel definition layer 3 covers the planar layer 104 and exposes respective first electrode 21. Specifically, the pixel definition layer 3 is provided with an opening 31 exposing the first electrodes 21, and the range of each light-emitting unit 001 may be defined by the pixel definition layer 3 and the opening 31 thereof. The material of the pixel definition layer 3 may be insulating materials such as silicon oxide and silicon nitride, which are not particularly limited herein.

The orthographic projection of any opening 31 on the substrate 101 is located within the first electrode 21 exposed thereby, that is, the opening 31 is not larger than the first electrode 21 exposed thereby. In some embodiments of the present disclosure, the pixel definition layer 3 has an extension portion, the extension portion is located on the surface of the first electrode 21 away from the substrate 101 and covers the edge of the first electrode 21. The opening 31 is provided in the extension portion, so that the extension portion is an annular structure with the opening 31. The shape of the opening 31 may be a polygon such as a rectangle, a pentagon, a hexagon, but not necessarily a regular polygon. The shape of the opening 31 may also be other shapes such as an ellipse, which is not particularly limited here.

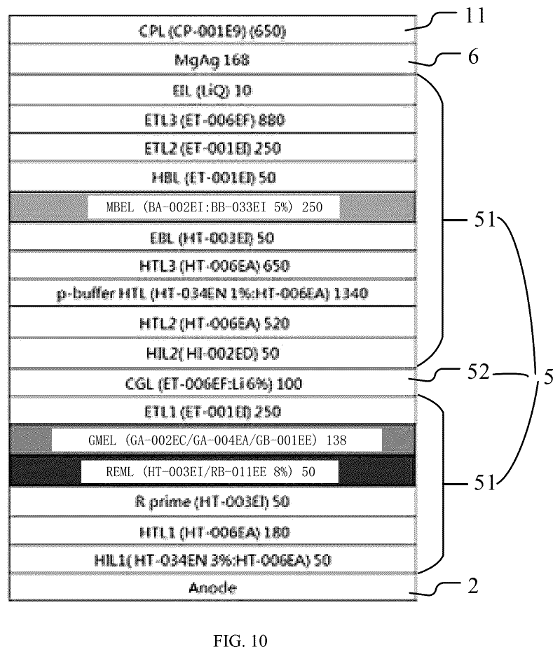

As shown in FIG. 4 and FIG. 10, the light-emitting layer 5 covers the pixel definition layer 3 and the first electrode 21, and an area of the light-emitting layer 5 located in the opening 31 and overlapped with the first electrode layer 2 is used for forming the light-emitting unit 001. That is, the respective light-emitting unit 001 may share the same light-emitting layer 5, that is, the parts of the light-emitting layer 5 located in different openings 31 belong to different light-emitting units 001. In addition, since the respective light-emitting unit 001 shares the light-emitting layer 5, the light-emitting colors of different light-emitting units 001 are the same.

In some embodiments of the present disclosure, as shown in FIG. 10, a light-emitting unit 001 may include a plurality of light-emitting devices, each of which includes a first electrode 21, a second electrode 6, and a plurality of light-emitting sublayers 51 between the first electrode 21 and the second electrode 6. The light-emitting devices of the same light-emitting unit 001 may share the same first electrode 21 and the same second electrode 6. That is, the same light-emitting unit 001 may have only one first electrode 21 and one second electrode 6.

For example, as shown in FIG. 10, the light-emitting layer 5 may include multiple layers of light-emitting sub-layers 51 connected in series along the direction away from the substrate 101. At least one light-emitting sub-layer 51 is connected in series with an adjacent light-emitting sub-layer 51 through the charge generating layer 52. When electrical signals are applied to the first electrode 21 and the second electrode 6, each light-emitting sub-layer 51 can emit light, and different light-emitting sub-layers 51 may be used to emit light of different colors.

Further, as shown in FIG. 10, any light-emitting sub-layer 51 may include a hole injection layer (HIL), a hole transport layer (HTL), a light-emitting material layer (EL), electron transport layer (ETL) and electron injection layer (EIL), the specific light-emitting principle will not be described in detail here. The numbers of hole injection layer, hole transport layer, electron transport layer and electron injection layer are not limited here. Respective light-emitting sublayers 51 may share one or more of the hole injection layer, the hole transport layer, the electron transport layer, and the electron injection layer. Meanwhile, the charge generating layer 52 may be provided between at least two adjacent light-emitting sub-layers 51, so that the two light-emitting sub-layers 51 are connected in series.

In some embodiments of the present disclosure, as shown in FIG. 10, the light-emitting layer 5 may include three light-emitting sub-layers 51 with different colors, namely, a first light-emitting sub-layer 51 that emits red light, and a second light-emitting sub-layer 51 that emits green light, and a third light-emitting sub-layer 51 that emits blue light. When the first light-emitting sub-layer 51, the second light-emitting sub-layer 51 and the third light-emitting sub-layer 51 emit light simultaneously, the light-emitting layer 5 can emit white light. The first light-emitting sub-layer 51 and the second light-emitting sub-layer 51 share a hole injection layer, a hole transport layer, an electron transport layer and an electron injection layer, and the light-emitting material layer of the second light-emitting sub-layer 51 is disposed on a surface of the light-emitting material layer of the first light-emitting sub-layer 51 away from the surface of the substrate 101, so that the first light-emitting sub-layer 51 and the second light-emitting sub-layer 51 are directly connected in series. The surface of the second light-emitting sublayer 51 facing away from the substrate 101 may be provided with the charge generation layer 52. The third light-emitting sublayer 51 shares an electron injection layer with the first light-emitting sublayer 51 and the second light-emitting sublayer 51, and the hole injection layer of the third light-emitting sublayer 51 is provided on the surface of the charge generation layer 52 away from the substrate 101, thereby the third light-emitting sublayer 51 may be connected in series with the second light-emitting sublayer 51.

As shown in FIGS. 4-8, the second electrode 6 covers the light-emitting layer 5, and the orthographic projection of the second electrode 6 on the substrate 101 can cover the pixel region 110 and extend into the peripheral region 120. The respective light-emitting unit 001 may share the same second electrode 6. When the voltage difference between the second electrode 6 and the first electrode 21 reaches a voltage difference that enables the light-emitting layer 5 to emit light, the light-emitting layer 5 can emit light. Therefore, the light-emitting layer 5 can be controlled to emit light by controlling the voltages of the power supply signal input to the second electrode 6 and the driving signal input to the first electrode 21.

As shown in FIGS. 4-8, in order to realize color display, the display panel may further include a color filter layer 7, the color filter layer 7 is disposed on the side of the second electrode 6 away from the substrate 101 and includes a plurality of filter parts 71. Each first electrode 21 and each filter part 71 are one-to-one aligned with each other in a direction perpendicular to the substrate 101, that is, the orthographic projection of a filter part 71 on the planar layer 104 at least partially overlaps with a first electrode 21. Each filter part 71 includes at least three color filter parts 71, for example, a filter part 71 that can transmit red light, a filter part 71 that can transmit green light, and a filter part 71 that can transmit blue light. After the light emitted by each light-emitting unit 001 is filtered by the light-filtering part 71, monochromatic light of different colors can be obtained, thereby realizing color display. A filter part 71 and its corresponding light-emitting unit 001 can constitute a sub-pixel, and the color of light emitted by any sub-pixel is the color of light transmitted by the filter part 71. A plurality of sub-pixels can constitute a pixel, and the light-emitting colors of the sub-pixels of the same pixel are different.

The shape of the orthographic projection of the filter part 71 on the substrate 101 may be the same as the shape of the opening 31 of the pixel definition layer 3, and the orthographic projection of each opening 31 on the substrate 101 is located in the orthographic projection of each filter part 71 on the substrate 101 in a one-to-one correspondence.

As shown in FIGS. 4-8, the color filter layer 7 may further include a light shielding portion 72 separating the filter parts 71. The light shielding portion 72 does not transmit light, and shields the area between the two light-emitting units 001. The filter part 71 may be directly spaced from the filter part 71 by using a light-shielding material. Alternatively, in some embodiments of the present disclosure, adjacent filter parts 71 can be stacked in a region corresponding to the region between two adjacent light-emitting units 001, and the colors of the light transmitted through the two are different, so that the stacked region is opaque.

In addition, in some embodiments of the present disclosure, on the basis that the light-emitting layer 5 emits white light, in order to improve the brightness of the image, the color filter layer 7 may further include a transparent portion. In the direction perpendicular to the substrate 101, the transparent portion may be aligned to the light-emitting unit 001, so that the color filter layer 7 can also transmit white light, and can increase the brightness by the white light.

In order to improve the light extraction efficiency, a light extraction layer 11 may be covered on the side of the second electrode 6 away from the substrate 101 to improve brightness. Further, the light extraction layer 11 may directly cover the surface of the second electrode 6 away from the substrate 101.

In order to facilitate the connection of the second electrode 6 with the driving circuit, in some embodiments of the present disclosure, the first electrode layer 2 further includes a transfer ring. The orthographic projection of the transfer ring on the substrate 101 is located in the peripheral region 120, and the transfer ring may be connected to the peripheral circuit and surround the pixel area 110. The second electrode 6 can be connected with the transfer ring, so that the second electrode 6 can be connected with the peripheral circuit through the transfer ring, so that the driving signal can be applied to the second electrode 6 by the peripheral circuit. The pattern of the transfer ring may be the same as the pattern of the first electrode 21 in the pixel region 110, so as to improve the uniformity of the pattern of the first electrode layer 2.

As shown in FIGS. 4-8, in some embodiments of the present disclosure, the display panel of the present disclosure may further include a first encapsulation layer 8, which may be provided on the side of the second electrode 6 away from the substrate 101 and between the color filter layer 7 and the second electrode 6, and be used to block the erosion of external moisture and oxygen. The first encapsulation layer 8 may be a single-layer or multi-layer structure, for example, the first encapsulation layer 8 may include a first encapsulation sub-layer 81, a second encapsulation sub-layer 82 and a third encapsulation sub-layer 83 that are sequentially stacked in a direction away from the substrate 101. The materials of the first encapsulation sublayer 81 and the second encapsulation sublayer 82 can be inorganic insulating materials such as silicon nitride and silicon oxide, and the second encapsulation sublayer 82 can be made of ALD (atomic layer deposition) process. The material of the third encapsulation sub-layer 83 may be an organic material, which may be formed by an MLD (molecular layer deposition) process. Of course, the first encapsulation layer 8 may also adopt other structures, and the structure of the first encapsulation layer 8 is not particularly limited herein.

In addition, in some embodiments of the present disclosure, the display panel of the present disclosure may further include a transparent cover plate 10, which may cover the side of the color filter layer 7 away from the substrate 101, and the transparent cover plate 10 may be a single-layer or multi-layer structure. The material of the transparent cover plate 10 is not particularly limited here.

In some embodiments of the present disclosure, the display panel of the present disclosure may further include a second encapsulation layer 9, which may cover the surface of the color filter layer 7 away from the substrate 101, so as to achieve planarization, to facilitate covering the transparent cover plate 10, to improve the encapsulation effect, and to further block moisture and oxygen. The second encapsulation layer 9 may have a single-layer or multi-layer structure, and may include inorganic materials such as silicon nitride and silicon oxide, or may include organic materials. The structure of the second encapsulation layer 9 is not particularly limited herein.

The solution of the display panel of the present disclosure for solving the problem of cross-color is described in detail below.

Combined with the above analysis of the related art, since each light-emitting unit 001 shares the light-emitting layer 5, the carriers (for example, holes) of one light-emitting unit 001 may move to other light-emitting units 001 through film layers such as the charge generation layer 52, especially to the adjacent light-emitting unit 001, that is, leakage occurs, which affects the purity of light-emitting. To this end, as shown in FIGS. 4-8, a conductive shielding layer 4 may be provided in the driving backplane 1, and the conductive shielding layer 4 is insulated from the wiring layer 103 but can conduct electricity. At the same time, the planar layer 104 can be formed with a second via hole exposing the conductive shielding layer 4, a second conductor D2 is formed in the second via hole, and the orthographic projection of the second conductor D2 on the substrate 101 is located outside the orthographic projection of the first electrode 21 on the substrate 101. The light-emitting layer 5 covers the second conductor D2, so that the conductive shielding layer 4 can be connected to the light-emitting layer 5 through the second conductor D2. Therefore, carriers can be absorbed by the conductive shielding layer 4 under the conduction of the second conductor D2, and moving of the carriers between the light-emitting units 001 can be presented, so as to avoid cross-color caused by leakage.

The conductive shielding layer 4 can be connected with the peripheral circuit in order to export the carriers. For example, the conductive shielding layer 4 can be connected with the second electrode 6. Although the light-emitting layer 5 also exists between the conductive shielding layer 4 and the second electrode 6, the light-emitting layer 5 is not driven to emit light as the conductive shielding layer 4 is connected to the second electrode 6. Of course, the conductive shielding layer 4 can also be directly grounded through the peripheral circuit, or connected to other signals, as long as the carriers can be derived, so as to avoid leakage between adjacent light-emitting units 001, and avoid the light-emitting layer 5 in the area corresponding to the conductive shielding layer 4 from emitting light.

As shown in FIGS. 4-8, the conductive shielding layer 4 may be a single-layer or multi-layer structure. For example, in some embodiments of the present disclosure, the conductive shielding layer 4 includes the first conductive layer 41, the second conductive layer 42 and the third conductive layer 43 stacked in sequence in a direction away from the substrate 101. The materials of the first conductive layer 41 and the third conductive layer 43 can be the same as the first layer 201 and the third layer 203 of the first electrode layer 2. For example, the materials of the first conductive layer 41 and the third conductive layer 43 are both metal titanium. The material of the second conductive layer 42 can be the same as the material of the second layer 202 of the first electrode layer 2. For example, the material of the second conductive layer 42 is aluminum metal. Therefore, the conductive shielding layer 4 can be formed by at least part of the process of forming the first electrode layer 2, so as to reduce costs. Meanwhile, the conductivity of the conductive shielding layer 4 can be made similar to that of the first electrode layer 2, so as to avoid absorbing too much or too little carriers, which may affect normal light emission.

As shown in FIGS. 4 to 8, in order to simplify the process, the conductive shielding layer 4 and a wiring layer 103 can be arranged in the same layer, that is, the conductive shielding layer 4 and a wiring layer 103 are formed simultaneously. In some embodiments of the present disclosure, the number of wiring layers 103 is multiple, and they are distributed in turn in the direction away from the substrate 101. The wiring layer 103 with the largest distance from the substrate 101 is the target wiring layer, and the target wiring layer is connected to the first electrode 21 through the first conductor D1. The conductive shielding layer 4 is arranged on the same layer as the target wiring layer. Further, for the first wiring layer 1031 and the second wiring layer 1032 above, the target wiring layer is the second wiring layer 1032.

As shown in FIGS. 4-8, in some embodiments of the present disclosure, a separation groove 32 may be formed at the pixel definition layer 3 correspond to the area outside the light-emitting unit 001, i.e., the area other than the opening 31. That is, the orthographic projection of the separation groove 32 on the substrate 101 is located outside the orthographic projection of the first electrode 21 on the substrate 101. The light-emitting layer 5 can be recessed at the separation groove 32, which is conducive to thinning, or even cuts off the charge generation layer 52 and at least part of the light-emitting sub-layer 51 in the light-emitting layer 5. The separation groove 32 of the pixel definition layer 3 may separate each light-emitting unit 001, and the light-emitting layer 5 is recessed at the separation groove 32, so that the light-emitting layer 5 needs to climb the sidewall of the separation groove 32, which is conducive to thinning or even breaking the light-emitting layer 5 at the separation groove 32, and further prevents the electricity leakage between adjacent light-emitting units 001 to improve cross-color.

In order to form the separation grooves 32, in some embodiments of the present disclosure, as shown in FIGS. 4 and 20, grooves 1041 may be provided in the planar layer 104 of the driving backplane 1. The thickness of the pixel definition layer 3 is smaller than the depth of the grooves 1041, and the separation grooves 32 are recessed at the grooves 1041. That is, the pixel definition layer 3 extends into the groove 1041 and covers the sidewalls and the bottom surface of the groove 1041, thereby forming the separation groove 32. That is, the separation groove 32 does not penetrate the pixel definition layer 3 in the depth direction. In order to prevent the grooves 1041 from exposing the wiring layers 103, each of the wiring layers 103 can be located on the side of the bottom surface of the grooves 1041 close to the substrate 101, and not exposed by the grooves 1041.

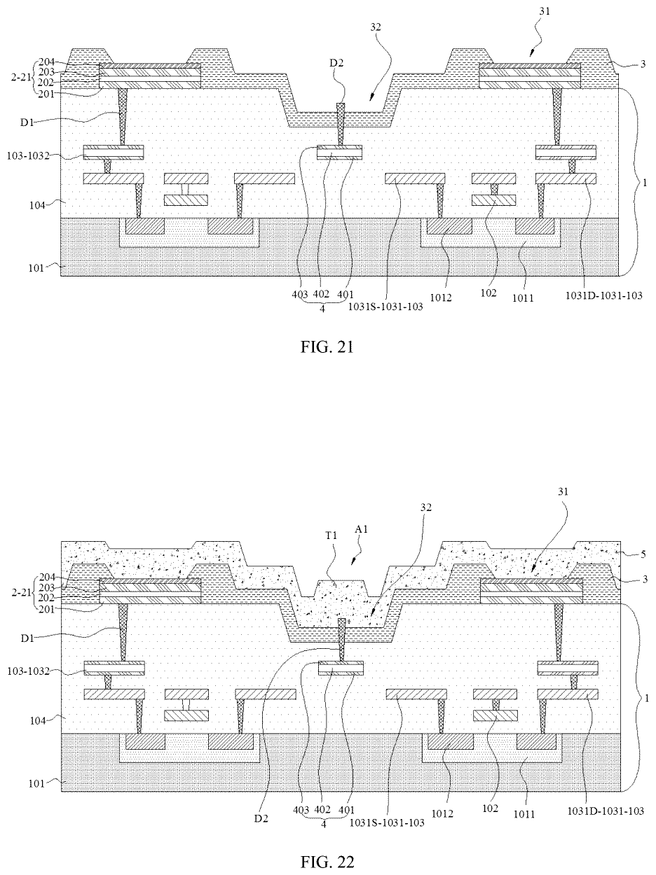

As shown in FIG. 4 and FIG. 21, in order to ensure that the separation groove 32 can recess the light-emitting layer 5, the depth of the separation groove 32 can be 800 μm-1000 μm, for example, 800 μm, 900 μm or 1000 μm. It should be noted that the bottom surface of the partition groove 32 is not limited to a flat surface, and may be a curved surface or an irregular surface. The depth of the separation groove 32 refers to the distance between a point of the bottom surface of the separation groove 32 closest to the substrate 101 and the substrate 101.

The orthographic projection of the second conductor D2 on the substrate 101 may be located within the orthographic projection of the separation groove 32 on the substrate 101. The second conductor D2 includes not only a portion inside the second via hole, but also a portion outside the second via hole and inside the separation groove 32, so that the second conductor D2 is in contact with the light-emitting layer 5, that is, embedded in the light-emitting layer 5. That is, the second conductor D2 can penetrate through the bottom of the separation groove 32 and enter the separation groove 32. Since the separation groove 32 is located in the groove 1041, the second conductor D2 that penetrates into the separation groove 32 naturally also penetrates into the groove 1041.

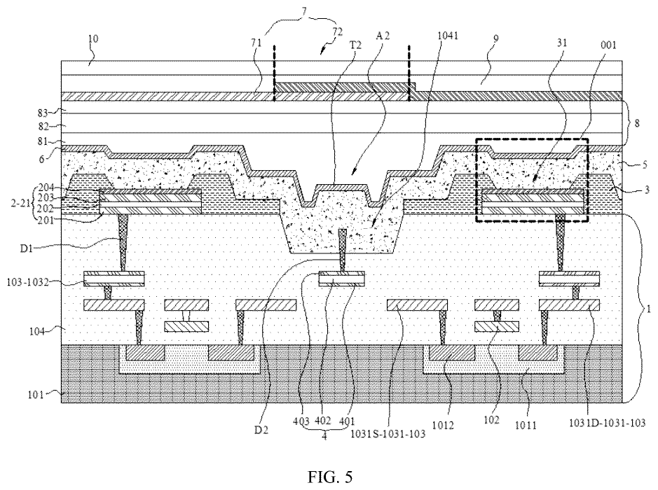

As shown in FIG. 5, in other embodiments of the present disclosure, the pixel definition layer 3 may not be recessed into the groove 1041, but may be disconnected at the groove 1041 to expose the groove 1041. That is, the orthographic projection of the pixel definition layer 3 on the substrate 101 is located outside the orthographic projection of the groove 1041 on the substrate 101. The light-emitting layer 5 can be recessed into the groove 1041, and the light-emitting layer 5 can be thinned or even disconnected at the groove 1041, which further prevents the electricity leakage between adjacent light-emitting units 001 and improves color cross-talk. The second conductor D2 penetrates into the groove 1041 in a direction away from the substrate 101 and is embedded in the light-emitting layer 5 so as to be connected with the light-emitting layer 5.

In some embodiments of the present disclosure, as shown in FIG. 4, since a part of the second conductor D2 is located in the groove 1041 and does not need to be connected to the first electrode 21, the length of the part of the second conductor D2 located in the groove 1041 in the direction perpendicular to the substrate 101 is smaller than the depth of the groove 1041. That is, the second conductor D2 does not protrude out from the groove 1041, as long as the second conductor D2 can be in contact with the light-emitting layer 5. In addition, in the direction perpendicular to the substrate 101, the length of the second conductor D2 may be smaller than the length of the first conductor D1, so as to prevent the part of the second conductor D2 penetrated into the groove 1041 from being too long and easily broken.

In addition, as shown in FIG. 4, in the direction perpendicular to the substrate 101, the distance between the surface of the first conductor D1 facing away from the substrate 101 and the bottom surface of the groove 1041 is greater than the length of the portion of the second conductor D2 located in the groove 1041.

It should be noted that, if the pixel definition layer 3 is formed with the separation groove 32 recessed into the groove 1041, in order to allow the second conductor D2 to penetrate through the pixel definition layer 3 and into the separation groove 32, the length of the portion of the second conductor D2 located in the groove 1041 in the direction perpendicular to the substrate 101 should be greater than the thickness of the pixel definition layer 3.

Further, since the length of the second conductor D2 is smaller than the length of the first conductor D1, it is difficult to form both of them in one process. Therefore, in some embodiments of the present disclosure, the first conductor D1 can be divided into a first conductive part D11 and a second conductive part D12, and the planar layer 104 can be divided into a first planar insulating layer P1 and a second planar insulating layer P2. The first planar insulating layer P1 covers each wiring layer 103 and the conductive shielding layer 4. The first conductive portion D11 of the first conductor D1 and the second conductor D2 are located at the first planar insulating layer P1, and the second conductive portion D12 of the first conductor D is located at the second planar insulating layer P2, thereby obtaining first conductors D1 and the second conductor D2 with different lengths. The groove 1041 may be formed at the second planar insulating layer P2 and may extend into the first planar insulating layer P1.

As shown in FIGS. 4-8, both the first via hole and the second via hole for accommodating the first conductor D1 and the second conductor D2 may be tapered structures. Therefore, the first conductor D1 and the second conductor D2 are also tapered structures. That is, the area of the surface thereof close to the substrate 101 is smaller than the area of the surface thereof facing away from the substrate 101. However, since the first conductive portion D11 of the first conductor D1 and the second conductor D2 are arranged in the same layer, the surface of the second conductor D2 facing away from the substrate 101 has the same area as the surface of the first conductive portion D11 facing away from the substrate 101, while both of them are smaller than the area of the surface of the second conductive portion D12 facing away from the substrate 101. That is, the area of the surface of the second conductor D2 facing away from the substrate 101 is smaller than the area of the surface of the second conductive portion D12 facing away from the substrate 101.

It should be noted that the planar layer 104 may be a multi-layer structure using the same material. For example, the first planar insulating layer P1 and the second planar insulating layer P2 are both made of silicon nitride, so the planar layer 104 can be regarded as an integral structure, but it is not limited to be formed in one process, and can also be formed in multiple times.

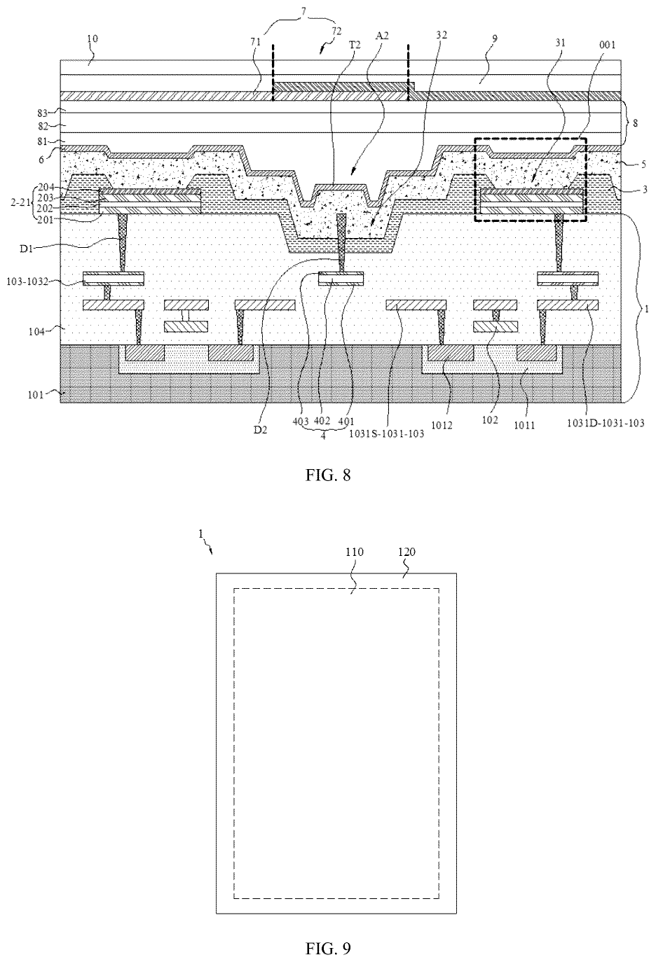

As shown in FIG. 8, in other embodiments of the present disclosure, the lengths of the first conductor D1 and the second conductor D2 in the direction perpendicular to the substrate 101 may also be the same, and may be formed simultaneously. For example, after the planar layer 104 is formed, a first via hole and a second via hole with the same depth can be formed simultaneously, and then the first conductor D1 is formed in the first via hole, and the second conductor D2 is formed in the second via hole.

In some embodiments of the present disclosure, when the pixel definition layer 3 is formed, it may cover the surface of the second conductor D2 away from the substrate 101, but at least the sidewall of the second conductor D2 should be exposed, so that the light-emitting layer 5 can be in contact with the second conductor D2. Of course, in order to increase the contact area between the second conductor D2 and the light-emitting layer 5, after the pixel definition layer 3 is formed, the pixel definition layer 3 covering the second conductor D2 can be removed, so that the surface of the second conductor D2 faces away from the substrate 101 is in contact with the light-emitting layer 5.

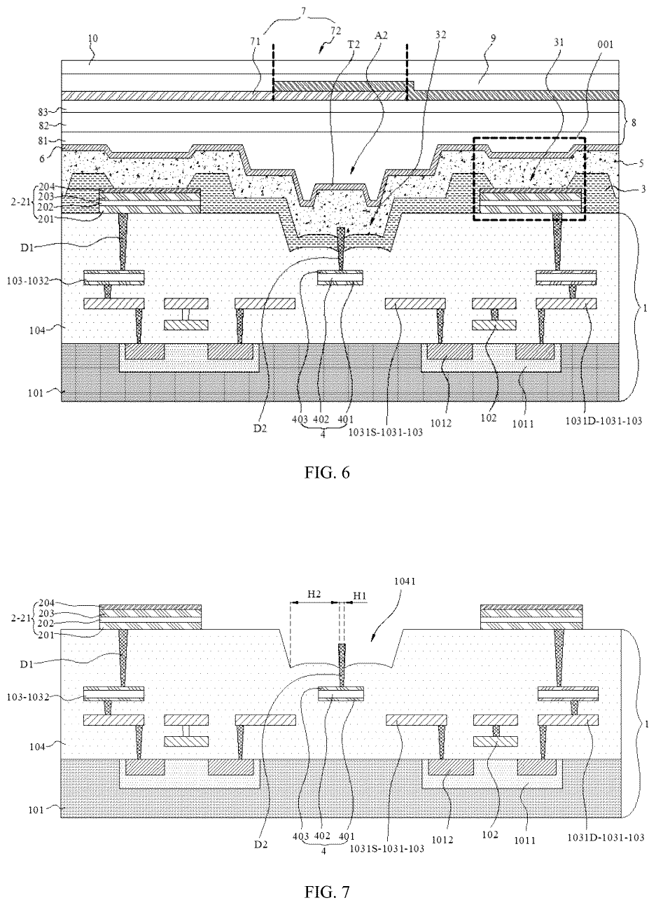

As shown in FIGS. 6 and 7, in some embodiments of the present disclosure, the bottom surface of the groove 1041 may have an opening area H1 and a peripheral area H2 located outside the opening area H1. The second conductor D2 penetrates through the opening region H1. The peripheral region H2 protrudes toward the side of the opening region H1 away from the substrate 101. The profile of the peripheral region H2 may be an arc or other smooth curve. Further, in order to ensure that the second conductor D2 can be in contact with the light-emitting layer 5, in the direction perpendicular to the substrate 101, the height of the peripheral region H2 protruding from the opening region H1 can be smaller than the length of the part of the second conductor D2 penetrated through the planar layer 104. That is, the surface of the second conductor D2 facing away from the substrate 101 may be located on the side of the peripheral region H2 facing away from the substrate 101. Correspondingly, if the pixel definition layer 3 extends to the sidewall and the bottom surface of the groove 1041, the pixel definition layer 3 may protrude in a region corresponding to the peripheral region H2.

In addition, due to the existence of the groove 1041 and the second conductor D2, the light-emitting layer 5 can be recessed to form a first recessed area A1 in the area corresponding to the groove 1041. The bottom surface of the first recessed area A1 corresponding to the area of the second conductor D2 is protruded to form a first protruding area T1.

Correspondingly, the second electrode 6 is recessed to form a second recessed area A2 in a region corresponding to the first recessed area A1. The bottom surface of the second recessed area A2 corresponds to the area of the first protruding area T1 and is protruded to form a second protruding area T2.

The materials of the above-mentioned first conductor D1 and the second conductor D2 may be metals such as tungsten, gold, and copper, and may also be conductive non-metallic materials, which are not specifically limited herein.

The effects of the display panel of the present disclosure are described below.

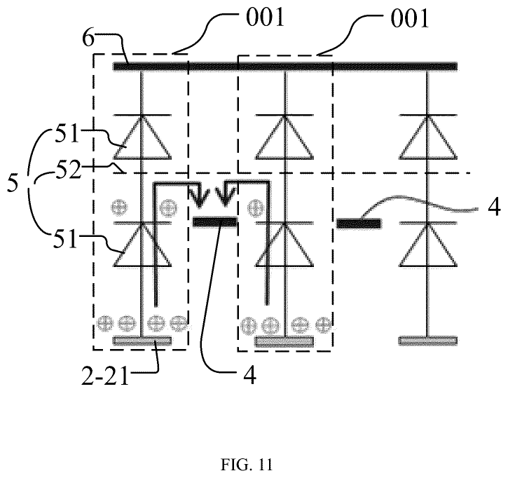

As shown in FIG. 11, the circuit principle of the conductive shielding layer 4 absorbing carriers is shown. It can be seen that the carriers (holes) between two adjacent light-emitting units 001 are absorbed by the conductive shielding layer 4, electricity leakage between the two light-emitting units 001 is avoided.

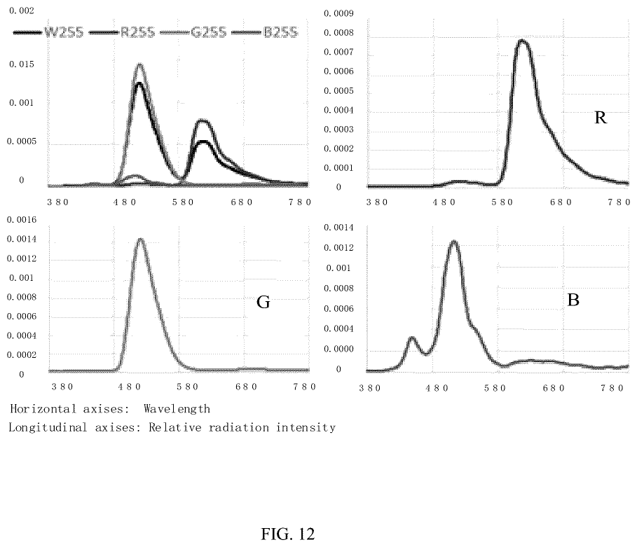

As shown in FIG. 12, a spectrogram in which three sub-pixels of red (R), green (G), and blue (B) are simultaneously lit and spectrograms in which they are lit up respectively are shown. Comparing FIG. 3 with the spectrogram of the related art, it can be seen that in the display panel of the present disclosure, when the three sub-pixels are respectively lit, the light of different color is significantly reduced, which improves the color gamut of the entire display panel. According to calculations, the color gamut index (NTSC) of the display panel can reach 80%.

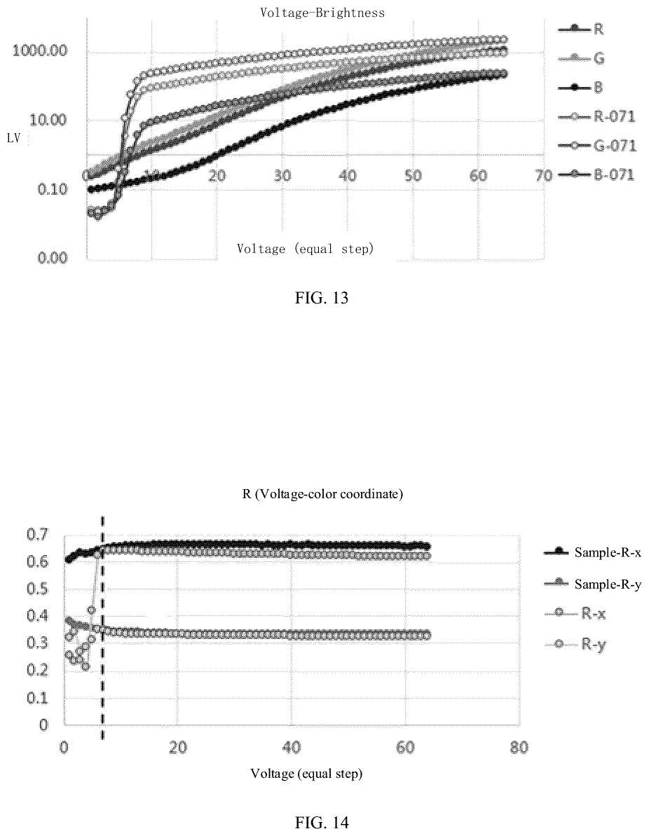

As shown in FIG. 13, the voltage-brightness graphs of three sub-pixels of red (R), green (G), and blue (B) are shown. The R, G and B graphs are the graphs of the three sub-pixels in an embodiment of the present disclosure, and R-071, G-071 and B-071 are the graphs of the three sub-pixels in the related art. FIGS. 14-16 respectively show the voltage-color coordinate graphs of three sub-pixels of red (R), green (G), and blue (B). The sample-R-x, sample-R-y, sample-G-x, sample-G-y, sample-B-x, sample-B-y graphs are color coordinate graphs of three sub-pixels in an embodiment of the present disclosure, and the R-x, R-y, G-x, G-y, B-x, B-y graphs are the color coordinate graphs of the three sub-pixels in the related art.

It can be seen from FIG. 14-FIG. 16 that the display panel in the related art has obvious brightness and color coordinate changes under low pressure (left side of the dotted line). In addition, there are jumping and flipping problems with voltage changes, which makes Gamma debugging difficult at low gray levels, and color bars are more likely to occur. In the display panel according to the embodiment of the present disclosure, the amplitude of each monochromatic color coordinate changing with the voltage is significantly reduced, which is beneficial to Gamma debugging, and the graphs are smooth without jumping problems.

To sum up, it can be seen that some embodiments of the display panel of the present disclosure can prevent electricity leakage, thereby avoiding the problem of color crossover.

The present disclosure also provides a method for manufacturing display panel, the display panel may be the display panel of any of the above-mentioned embodiments, and its structure and effects will not be described in detail here.

As shown in FIG. 4-FIG. 8 and FIG. 17-FIG. 22, the manufacturing method may include steps S110-S170, wherein:

Step S110, forming a substrate.

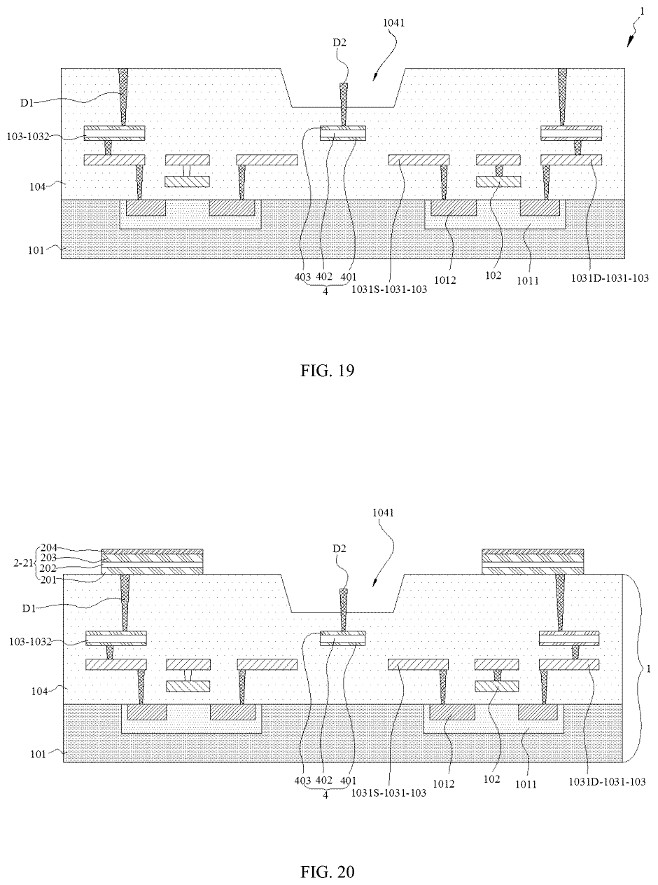

Step S120, forming at a side of the substrate a conductive shielding layer, at least one wiring layer, a planar layer covering the wiring layer and the conductive shielding layer, a first conductor and a second conductor, wherein the conductive shielding layer is insulated from the wiring layer, the first conductor is disposed in the planar layer and connected to one of the wiring layer, and the second conductor is penetrated into the planar layer from a side of the planar layer away from the substrate and connected to the conductive shielding layer, as shown in FIG. 18 and FIG. 19.

Step S130, forming a first electrode layer at a surface of the planar layer away from the substrate, wherein the first electrode layer includes a plurality of first electrodes distributed at intervals, an orthographic projection of the conductive shielding layer on the substrate is spaced apart from an orthographic projection of the first electrode on the substrate, and the first electrode is connected to the first conductor, as shown in FIG. 20.

Step S140, forming a pixel definition layer covering the planar layer and exposing respective first electrode, as shown in FIG. 21.

Step S150, forming a light-emitting layer covering the pixel definition layer and the first electrode, wherein the light-emitting layer is connected to the second conductor, as shown in FIG. 22.

Step S160, forming a second electrode covering the light-emitting layer, as shown in FIG. 4.

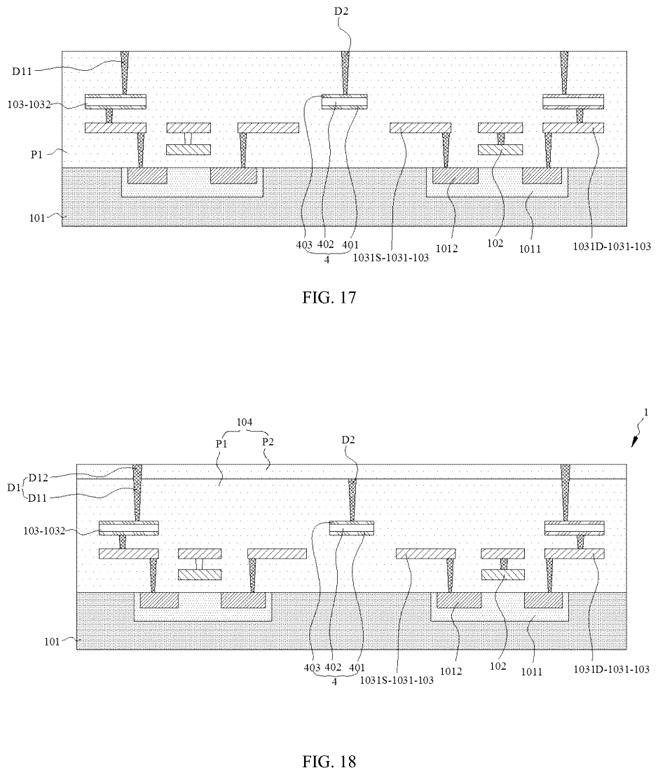

In some embodiments of the present disclosure, as shown in FIGS. 17-19, the step S120 may include steps S1210-S1260, wherein:

Step S1210, forming the conductive shielding layer, at least one wiring layer, and a first planar insulating layer covering the conductive shielding layer and the wiring layer on one side of the substrate.

The first planar insulating layer P1, the respective wiring layer 103 and the conductive shielding layer 4 may be formed in multiple processes. The first planar insulating layer P1 may be an integral structure formed of the same material, but is not limited to be formed at one time.

Step S1220, forming a first via hole and a second via hole extending toward the substrate in the first planar insulating layer, wherein the one of the wiring layer is exposed by the first via hole, and the conductive shielding layer is exposed by the second via hole.

For example, the first via hole may expose the second wiring layer 1032.

Step S1230, forming a first conductive portion in the first via hole, and forming a second conductor in the second via hole, as shown in FIG. 14.

A part of the first conductor D1, i.e., the first conductive portion D11, may be formed simultaneously with the second conductor D2.

Step S1240, forming a second planar insulating layer covering the first planar insulating layer, wherein the planar layer includes the first planar insulating layer and the second planar insulating layer, as shown in FIG. 18.

The second planar insulating layer P2 can be formed of the same material as the first planar insulating layer P1, so that the planar layer 104 can be an integral structure of the same material. The thickness of the second planar insulating layer P2 may be smaller than that of the first planar insulating layer P1, but not limited thereto.

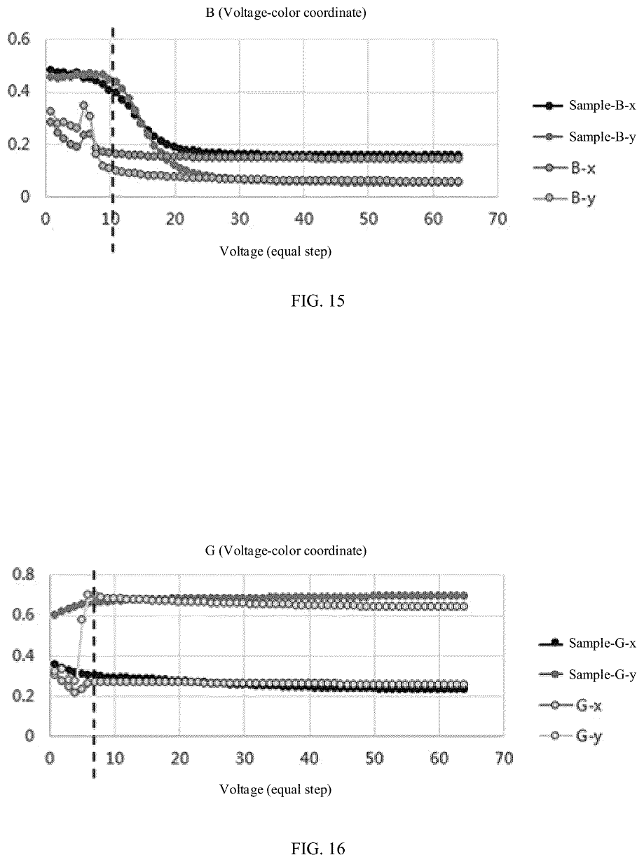

It should be noted that, in order to facilitate the description of the formation sequence of the second planar insulating layer P2 and the first planar insulating layer P1, FIG. 14 shows the boundary line between the second planar insulating layer P2 and the first planar insulating layer P1, but if the second planar insulating layer P2 and the first planar insulating layer P1 are formed of the same material, even if they are not formed at the same time, after the second planar insulating layer P2 is formed, the second planar insulating layer P2 and the first planar insulating layer P1 can be regarded as an integrated structure. Therefore, in FIG. 15, the second planar insulating layer P2 and the first planar insulating layer P1 are drawn as an integrated structure, and the boundary between the second planar insulating layer P2 and the first planar insulating layer P1 in FIG. 14 is omitted. In essence, both the embodiments of FIGS. 14 and 15 include a second planar insulating layer P2 and a first planar insulating layer P1.

Step S1250, forming a third via hole in connection with the first via hole in the second planar insulating layer.

The third via hole and the first via hole together constitute a via hole for accommodating the first conductor D1, and the diameter of the third via hole and the first via hole may be the same or different.

Step S1260, forming a second conductive portion connected to the first conductive portion in the third via hole, where the first conductor includes the first conductive portion and the second conductive portion, as shown in FIG. 18.

The first conductive portion D11 and the second conductive portion D12 can be made of the same material, so that the conductive properties are consistent.

In other embodiments of the present disclosure, as shown in FIG. 8, step S120 may include steps S1210-S1230, wherein:

Step S1210, forming the conductive shielding layer, at least one wiring layer, and the planar layer covering the conductive shielding layer and the wiring layer on one side of the substrate.

The manner of forming the planar layer 104 may be the same as that of the first planar insulating layer P1 in the above-described embodiment.

Step S1220, forming a first via hole and a second via hole extending toward the substrate in the planar layer, wherein the one of the wiring layer is exposed by the first via hole, and the conductive shielding layer is exposed by the second via hole.

The depths of the first via hole and the second via hole may be the same, and the wiring layer 103 exposed by the first via hole and the conductive shielding layer 4 exposed by the second via hole are provided in the same layer.

Step S1230, forming the first conductor in the first via hole, and forming the second conductor in the second via hole.

The first conductor D1 and the second conductor D2 may be formed at the same time, and both have the same length in a direction perpendicular to the substrate 101.

In some embodiments of the present disclosure, after forming the first electrode layer and before forming the pixel definition layer, that is, after step S130 and before step S140, the manufacturing method of the present disclosure may further include:

Step S180, forming a groove on the planar layer, wherein an orthographic projection of the groove on the substrate is outside the orthographic projection of the first electrode on the substrate, and the second conductor is penetrated into the groove in a direction away from the substrate, as shown in FIG. 5.

The pixel definition layer 3 can be recessed by the groove 1041 to form the separation groove 32, and the pixel definition layer 3 is extended to the sidewall and bottom surface of the groove 1041 to form the separation groove. Accordingly, the light-emitting layer 5 may be recessed at the separation groove 32.

Correspondingly, step S140 may include steps S1410 and S1420, wherein:

Step S1410, forming the pixel definition layer covering the second planar insulating layer, wherein the pixel definition layer is recessed to form the separation groove at the groove, and the second conductor penetrates into the separation groove in a direction away from the substrate.

The orthographic projection of the separation groove 32 on the substrate 101 is located outside the orthographic projection of the first electrode 21 on the substrate 101.

In addition, based on some embodiments of the display panel above, the conductive shielding layer 4 may be disposed in the same layer as the second wiring layer 1032, that is, the conductive shielding layer 4 may be formed simultaneously with the second wiring layer 1032. For example, the conductive shielding layer 4 includes the first conductive layer 41, the second conductive layer 42 and the third conductive layer 43, and the second wiring layer 1032 may include three conductive layers respectively formed simultaneously with the first conductive layer 41, the second conductive layer 42 and the second conductive layer 43. Alternatively, the second wiring layer 1032 may be a single-layer structure including a conductive film layer, while the conductive film layer may be simultaneously with one of the first conductive layer 41, the second conductive layer 42 and the third conductive layer 43. There is no particular limitation on the process in which the conductive shielding layer 4 and the second wiring layer 1032 can be formed simultaneously.

In other embodiments of the present disclosure, the pixel definition layer 3 may expose the groove 1041, that is, the orthographic projection of the pixel definition layer 3 on the substrate 101 is located outside the orthographic projection of the groove 1041 on the substrate 101, so that light is light-emitting layer 5 may be recessed at the groove 1041, as shown in FIG. 18 and FIG. 20.

In addition, after step S160, the manufacturing method of the present disclosure may further include step S170:
forming a color filter layer including a plurality of filter parts on the side of the second electrode facing away from the substrate, wherein each first electrode and each filter part are one-to-one aligned with each other in a direction perpendicular to the substrate 101, as shown in FIG. 4-FIG. 8.

The structure in each step of the manufacturing method of the embodiment of the present disclosure has been described in detail in the embodiment of the display panel above, and will not be described in detail here.

It should be noted that although the various steps of the manufacturing method in the present disclosure are described in a specific order in the drawings, this does not require or imply that the steps must be performed in this specific order, or that all of the steps shown must be performed to achieve the desired result. Additionally or alternatively, certain steps may be omitted, multiple steps may be combined into one step for execution, and/or one step may be decomposed into multiple steps for execution, and the like.

An embodiment of the present disclosure further provides a display device, including the display panel of any of the foregoing embodiments. The structure of the display panel may refer to the embodiments of the display surface above, which will not be repeated here. The display device of the present disclosure may be an electronic device with an image display function, such as a mobile phone and a tablet computer, which will not be listed one by one here.

Other embodiments of the present disclosure will readily occur to those skilled in the art upon consideration of the specification and practice of the invention disclosed herein. This application is intended to cover any variations, uses, or adaptations of the present disclosure that follow the general principles of the present disclosure and include common knowledge or techniques in the technical field not disclosed by the present disclosure. The specification and examples are to be regarded as exemplary only, with the true scope and spirit of the disclosure being indicated by the appended claims.

1. A display panel, comprising:
a substrate;
at least one wiring layer, disposed at a side of the substrate;
a conductive shielding layer, disposed at the side of the substrate same as the wiring layer, and insulated from the wiring layer;
a planar layer, covering the wiring layer and the conductive shielding layer;
a first electrode layer, disposed at a surface of the planar layer away from the substrate, and comprising a plurality of first electrodes distributed at intervals and connected to one of the wiring layer through a first conductor disposed in the planar layer;
a pixel definition layer, covering the planar layer and exposing respective first electrode;
a light-emitting layer, covering the pixel definition layer and the first electrode, and is connected to the conductive shielding layer through a second conductor at least partially disposed in the planar layer, wherein an orthographic projection of the second conductor on the substrate is located outside an orthographic projection of the first electrode on the substrate; and
a second electrode, covering the light-emitting layer.

2. The display panel according to claim 1, wherein the pixel definition layer is provided with a separation groove recessed toward the substrate, and an orthographic projection of the separation groove on the substrate is located outside the orthographic projection of the first electrode on the substrate; and the light-emitting the layer is recessed at the separation groove; and
the second conductor is penetrated into the separation groove in a direction away from the substrate, and is embedded in the light-emitting layer.

3. The display panel according to claim 2, wherein the planar layer is provided with a groove, and an orthographic projection of the groove on the substrate is located outside the orthographic projection of the first electrode on the substrate; and
the pixel definition layer is extended to a sidewall and a bottom surface of the groove to form the separation groove.

4. The display panel according to claim 3, wherein the pixel definition layer is covered on a surface of the second conductor away from the substrate, and the pixel definition layer is intermittently disposed on the sidewall of the second conductor.

5. The e display panel according to claim 1, wherein the planar layer is provided with a groove, and an orthographic projection of the groove on the substrate is located outside the orthographic projection of the first electrode on the substrate;
an orthographic projection of the pixel definition layer on the substrate is located outside the orthographic projection of the groove on the substrate; and the light-emitting layer is recessed at the groove; and
the second conductor is penetrated into the groove in a direction away from the substrate, and is embedded in the light-emitting layer.

6-8. (canceled)

9. The display panel according to claim 3, wherein, in a direction perpendicular to the substrate, a length of a portion of the second conductor located in the groove is smaller than a depth of the groove.

10. The display panel according to claim 9, wherein, in a direction perpendicular to the substrate, a distance between a surface of the first conductor facing away from the substrate and a bottom surface of the groove is greater than the length of the portion of the second conductor located in the groove.

11. The display panel according to claim 3, wherein a bottom surface of the groove has an opening area and a peripheral area outside the opening area, the second conductor is passed through the opening area, and the peripheral area is protruded toward a side of the opening area facing away from the substrate.

12. The display panel according to claim 11, wherein, in a direction perpendicular to the substrate, a height of the peripheral region protruding from the opening region is smaller than a height of a portion of the second conductor passing through over the planar layer.

13-15. (canceled)

16. The display panel according to claim 1, wherein the conductive shielding layer is connected to the second electrode.

17-18. (canceled)

19. The display panel according to claim 1, wherein the light-emitting layer comprises multiple layers of light-emitting sub-layers connected in series, and at least one of the light-emitting sub-layers is connected in series with an adjacent one of the light-emitting sub-layers through a charge generating layer.

20. The display panel according to claim 3, wherein the light-emitting layer is recessed to form a first recessed area in a region corresponding to the groove; and an area of a bottom surface of the first recessed area corresponding to the second conductor is protruded to form a first protruding area; and
the second electrode is recessed to form a second recessed area in an area corresponding to the first recessed area; and an area of a bottom surface of the second recessed area corresponding to the first protruding area is protruded to form a second protruding area.

21. A method for manufacturing display panel, comprising:
forming a substrate;
forming at a side of the substrate a conductive shielding layer, at least one wiring layer, a planar layer covering the wiring layer and the conductive shielding layer, a first conductor and a second conductor, wherein the conductive shielding layer is insulated from the wiring layer, the first conductor is disposed in the planar layer and connected to one of the wiring layer, and the second conductor is penetrated into the planar layer from a side of the planar layer away from the substrate and connected to the conductive shielding layer;
forming a first electrode layer at a surface of the planar layer away from the substrate, wherein the first electrode layer comprises a plurality of first electrodes distributed at intervals, an orthographic projection of the conductive shielding layer on the substrate is spaced apart from an orthographic projection of the first electrode on the substrate, and the first electrode is connected to the first conductor;
forming a pixel definition layer covering the planar layer and exposing respective first electrode;
forming a light-emitting layer covering the pixel definition layer and the first electrode, wherein the light-emitting layer is connected to the second conductor; and
forming a second electrode covering the light-emitting layer.

22. The method according to claim 21, wherein after forming the first electrode layer and before forming the pixel definition layer, the method further comprises:
forming a groove on the planar layer, wherein an orthographic projection of the groove on the substrate is outside the orthographic projection of the first electrode on the substrate, and the second conductor is penetrated into the groove in a direction away from the substrate;
wherein the pixel definition layer is extended to a sidewall and a bottom surface of the groove to form a separation groove; and the light-emitting layer is recessed at the separation groove.

23. The method according to claim 21, wherein after forming the first electrode layer and before forming the pixel definition layer, the method further comprises:
forming a groove on the planar layer, wherein an orthographic projection of the groove on the substrate is outside the orthographic projection of the first electrode on the substrate, and the second conductor is penetrated into the groove in a direction away from the substrate;
wherein an orthographic projection of the pixel definition layer on the substrate is outside the orthographic projection of the groove on the substrate; and the light-emitting layer is recessed at the separation groove.

24. The method according to claim 22, wherein the forming at the side of the substrate the conductive shielding layer, at least one wiring layer, the planar layer covering the wiring layer and the conductive shielding layer, the first conductor and the second conductor comprises:
forming the conductive shielding layer, at least one wiring layer and a first planar insulating layer covering the wiring layer and the conductive shielding layer at the side of the substrate;
forming a first via hole and a second via hole extending toward the substrate in the first planar insulating layer, wherein the one of the wiring layer is exposed by the first via hole, and the conductive shielding layer is exposed by the second via hole;
forming a first conductive portion in the first via hole, and forming the second conductor in the second via hole;
forming a second planar insulating layer covering the first planar insulating layer, wherein the planar layer comprises the first planar insulating layer and the second planar insulating layer;
forming a third via hole in connection with the first via hole in the second planar insulating layer; and
forming a second conductive portion connected to the first conductive portion in the third via hole, wherein the first conductor comprises the first conductive portion and the second conductive portion.

25. The method according to claim 22, wherein the forming at the side of the substrate the conductive shielding layer, at least one wiring layer, the planar layer covering the wiring layer and the conductive shielding layer, the first conductor and the second conductor comprises:
forming the conductive shielding layer, at least one wiring layer and the planar layer covering the wiring layer and the conductive shielding layer at the side of the substrate;
forming a first via hole and a second via hole extending toward the substrate in the planar layer, wherein the one of the wiring layer is exposed by the first via hole, and the conductive shielding layer is exposed by the second via hole; and
forming the first conductor in the first via hole, and forming the second conductor in the second via hole.

26. The method according to claim 21, wherein the conductive shielding layer and the one of the wiring layer are formed simultaneously.

27. The method according to claim 26, wherein the at least one wiring layer comprises multiple wiring layers distributed in sequence along a direction away from the substrate; and adjacent two wiring layers are connected;
the one of the wiring layer furthest away from the substrate is a target wiring layer, and the target wiring layer is connected to the first electrode through the first conductor; and
the conductive shielding layer and the target wiring layer are formed simultaneously.

28. A display device, comprising the display panel 20, wherein the display panel comprises:
a substrate;
at least one wiring layer, disposed at a side of the substrate;
a conductive shielding layer, disposed at the side of the substrate same as the wiring layer, and insulated from the wiring layer;
a planar layer, covering the wiring layer and the conductive shielding layer;
a first electrode layer, disposed at a surface of the planar layer away from the substrate, and comprising a plurality of first electrodes distributed at intervals and connected to one of the wiring layer through a first conductor disposed in the planar layer;
a pixel definition layer, covering the planar layer and exposing respective first electrode;
a light-emitting layer, covering the pixel definition layer and the first electrode, and is connected to the conductive shielding layer through a second conductor at least partially disposed in the planar layer, wherein an orthographic projection of the second conductor on the substrate is located outside an orthographic projection of the first electrode on the substrate; and
a second electrode, covering the light-emitting layer.
